(19) United States
(12) Patent Application Publication
(10) Pub. No.: US 2024/0347494 A1
(43) Pub. Date: Oct. 17, 2024

(54) SEMICONDUCTOR DEVICE

(71) Applicant: Murata Manufacturing Co., Ltd., Kyoto-fu (JP)

(72) Inventors: Mari SAJI, Nagaokakyo-shi (JP); Atsushi KUROKAWA, Nagaokakyo-shi (JP); Masahiro SHIBATA, Nagaokakyo-shi (JP)

(73) Assignee: Murata Manufacturing Co., Ltd., Kyoto-fu (JP)

(21) Appl. No.: 18/756,034

(22) Filed: Jun. 27, 2024

Related U.S. Application Data
(63) Continuation of application No. PCT/JP2022/046893, filed on Dec. 20, 2022.

(30) Foreign Application Priority Data
Jan. 7, 2022 (JP) 2022-001851

(51) Int. Cl. H01L 23/00; H01L 23/498; H01L 25/07

(52) U.S. Cl. CPC H01L 24/16; H01L 23/49811; H01L 25/072; H01L 24/13; H01L 2224/13014; H01L 2224/1601; H01L 2224/16137; H01L 2924/3512

(57) ABSTRACT

A semiconductor device includes a semiconductor substrate; at least one transistor located on the semiconductor substrate and including a plurality of semiconductor layers; an electrode provided for the transistor; an organic insulating film having an opening in a region overlapping the transistor and the electrode in plan view in a first direction perpendicular to the semiconductor substrate; and a bump located over the at least one transistor in plan view in the first direction and electrically connected to the electrode through the opening of the organic insulating film. The width of the bump in a second direction parallel to the semiconductor substrate is smaller than the width of the opening of the organic insulating film in the second direction.

### CROSS-REFERENCE TO RELATED APPLICATIONS

This application claims benefit of priority to International Patent Application No. PCT/JP2022/046893, filed Dec. 20, 2022, and to Japanese Patent Application No. 2022-001851, filed Jan. 7, 2022, the entire contents of each are incorporated herein by reference.

### BACKGROUND

### Technical Field The present disclosure relates to a semiconductor device.

### Background Art

Japanese Unexamined Patent Application Publication No. 2019-102724 describes a semiconductor device including a heterojunction bipolar transistor. The semiconductor device described in Japanese Unexamined Patent Application Publication No. 2019-102724 includes a bump located immediately above the transistor. The bump is electrically connected to the emitter electrode of the transistor through an opening of an organic insulating film (a resin film) covering the transistor.

### SUMMARY

In the case in which the bump overlaps the entire region of the mesa structure of the transistor, the heat dissipation characteristics are improved (specifically, the thermal resistance decreases), but there is a possibility that the reliability of the semiconductor device can decrease, for example, stress from the bump can cause a crack in the mesa structure.

Accordingly, the present disclosure provides a semiconductor device in which the stress generated in a transistor is reduced.

A semiconductor device according to an aspect of the present disclosure includes a semiconductor substrate; at least one transistor located on the semiconductor substrate and including a plurality of semiconductor layers; an electrode provided for the transistor; an organic insulating film having an opening in a region overlapping the transistor and the electrode in plan view in a first direction perpendicular to the semiconductor substrate; and a bump located over the at least one transistor in plan view in the first direction and electrically connected to the electrode through the opening of the organic insulating film. The width of the bump in a second direction parallel to the semiconductor substrate is smaller than the width of the opening of the organic insulating film in the second direction.

A semiconductor device according to an aspect of the present disclosure includes a semiconductor substrate; at least one transistor located on the semiconductor substrate and including a plurality of semiconductor layers; an electrode provided for the transistor; an organic insulating film having an opening in a region overlapping the transistor and the electrode in plan view in a first direction perpendicular to the semiconductor substrate; and a bump located over the at least one transistor in plan view in the first direction and electrically connected to the electrode through the opening of the organic insulating film. The width of the bump in a second direction parallel to the semiconductor substrate is equal to the width of the opening of the organic insulating film in the second direction.

In the semiconductor device of the present disclosure, the stress generated in a transistor is reduced.

### BRIEF DESCRIPTION OF THE DRAWINGS

FIG. 1 is a plan view of a semiconductor device according to a first embodiment;

FIG. 2 is a cross-sectional view taken along line II-II′ in FIG. 1;

FIG. 3 is a cross-sectional view of a semiconductor device according to a second embodiment;

FIG. 4 is a cross-sectional view of a semiconductor device according to a third embodiment;

FIG. 5 is a cross-sectional view of a semiconductor device according to a fourth embodiment;

FIG. 6 is an explanatory diagram for explaining manufacturing processes for the semiconductor device according to the fourth embodiment;

FIG. 7 is a cross-sectional view of a semiconductor device according to a fifth embodiment;

FIG. 8 is a cross-sectional view of a semiconductor device according to a modification example of the fifth embodiment;

FIG. 9 is an explanatory diagram for explaining manufacturing processes for the semiconductor device according to the fifth embodiment;

FIG. 10 is a cross-sectional view of a semiconductor device according to a sixth embodiment; and

FIG. 11 is a cross-sectional view of a semiconductor device according to a seventh embodiment.

### DETAILED DESCRIPTION

Hereinafter, embodiments of the semiconductor device according to the present disclosure will be described in detail with reference to the drawings. The embodiments are not intended to limit the present disclosure. Each embodiment is to show an example, and hence it goes without saying that constituents shown in different embodiments can be partially replaced or combined with one another. For a second embodiment and after, description of the items common to those of a first embodiment will be omitted, and only different points will be described. In particular, the same or similar operational advantages by the same or similar configurations will not be referred to in each embodiment.

### First Embodiment

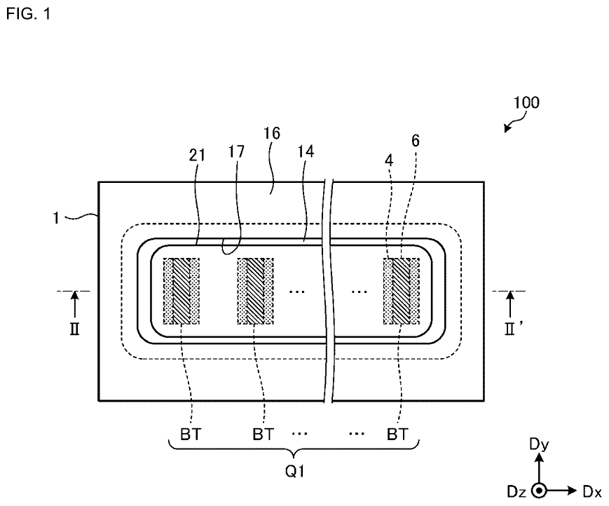

FIG. 1 is a plan view of a semiconductor device according to the first embodiment. FIG. 1 illustrates transistors BT without a detailed configuration of each transistor BT. FIG. 1 schematically illustrates the positional relationship of a mesa structure, including a base layer 4, and an emitter electrode 6 of each transistor.

As illustrated in FIG. 1, a semiconductor device 100 includes a semiconductor substrate 1, a transistor group Q1, a first organic insulating film 16, and a bump 21.

In the following description, one direction in the plane parallel to the surface of the semiconductor substrate 1 is defined as the X-axis direction Dx. The direction orthogonal to the X-axis direction Dx in the plane parallel to the surface of the semiconductor substrate 1 is defined as the Y-axis direction Dy. The direction orthogonal to the X-axis direction Dx and the Y-axis direction Dy is defined as the Z-axis direction Dz. The Z-axis direction Dz is perpendicular to the surface of the semiconductor substrate 1. The Z-axis direction Dz is an example of a “first direction”, and the X-axis direction Dx and the Y-axis direction Dy are examples of a “second direction”. In this specification, “plan view” is to show the positional relationship viewed in the Z-axis direction Dz.

The transistor group Q1 is located on the surface of the semiconductor substrate 1. The transistor group Q1 includes a plurality of transistors BT. Each transistor BT is a heterojunction bipolar transistor (HBT). Each transistor BT is also referred to as a unit transistor, which is defined as a smallest transistor composing the transistor group Q1. The transistors BT are electrically connected in parallel and compose the transistor group Q1.

The plurality of transistors BT in the transistor group Q1 are aligned in the X-axis direction Dx. A mesa structure, including the base layer 4, and the emitter electrode 6 of each of the transistors BT extend in the Y-axis direction Dy.

In FIG. 1, the transistor group Q1 includes three or more transistors BT. However, the number and arrangement of transistors BT are a mere example and can be changed as appropriate. The number of transistors BT needs only to be one or more. Although FIG. 1 illustrates one transistor group Q1 to facilitate understanding of the explanation, two or more transistor groups may be located on one and the same semiconductor substrate 1.

The bump 21 is located over the plurality of transistors BT of the transistor group Q1 in plan view. The bump 21 is electrically connected to the plurality of transistors BT through an opening 17 formed in the first organic insulating film 16. The bump 21 has an oval shape in plan view and extends in the X-axis direction Dx along the arrangement direction of the plurality of transistors BT. The bump 21 covers all of the plurality of transistors BT aligned in the X-axis direction Dx. The width of the bump 21 in the Y-axis direction Dy is larger than the width in the Y-axis direction Dy of the mesa structures, including the base layers 4, and the emitter electrodes 6 of the plurality of transistors BT.

Part of the bump 21 is located inside the opening 17 in the first organic insulating film 16 in plan view. In other words, the area of the part of the bump 21 is smaller than the area of the opening 17, and the outer periphery of the bump 21 is away from the inner periphery of the opening 17. The relationship between the bump 21 and the opening 17 formed in the first organic insulating film 16 will be described later in detail.

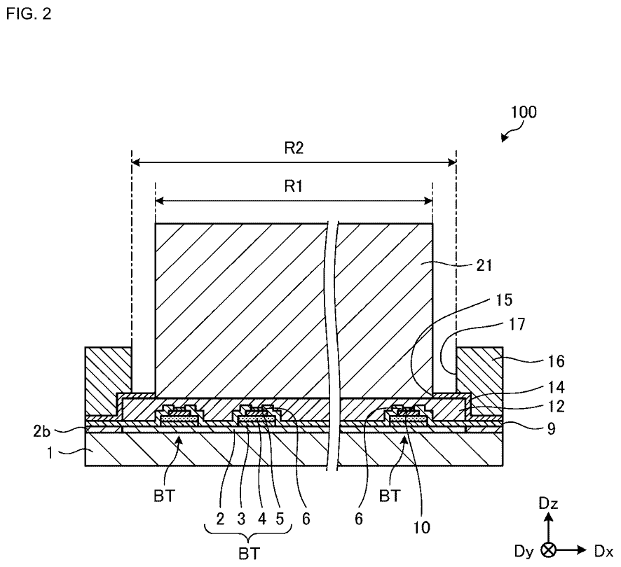

Next, the cross-sectional configuration of the semiconductor device 100 will be described in detail. FIG. 2 is a cross-sectional view taken along line II-II′ in FIG. 1. As illustrated in FIG. 2, in the semiconductor device 100, each transistor BT includes a sub-collector layer 2, a collector layer 3, the base layer 4, an emitter layer 5, and the emitter electrode 6. In each transistor BT, the sub-collector layer 2, the collector layer 3, the base layer 4, the emitter layer 5, and the emitter electrode 6 are laminated in this order on the semiconductor substrate 1. Although illustration is omitted in FIG. 2, the sub-collector layer 2 has collector electrodes, and each base layer 4 has a base electrode.

Of the semiconductor layers (the sub-collector layer 2, the collector layer 3, the base layer 4, and the emitter layer 5) of the transistor BT, the mesa structure in the present embodiment includes one or more semiconductor layers. For example, the mesa structure is a collector mesa including the collector layer 3 and the base layer 4.

More specifically, the semiconductor substrate 1 is, for example, a semi-insulating GaAs (gallium arsenide) substrate. The sub-collector layer 2 is formed on the semiconductor substrate 1. The sub-collector layer 2 is a high concentration n-type GaAs layer, the thickness of which is, for example, 0.5 μm or so. The collector layer 3 is formed on the sub-collector layer 2. The collector layer 3 is an n-type GaAs layer, the thickness of which is, for example, 1 μm or so. The base layer 4 is formed on the collector layer 3. The base layer 4 is a p-type GaAs layer, the thickness of which is, for example, 100 nm or so.

The emitter layer 5 is formed on the base layer 4. Although illustration is omitted, the emitter layer 5 includes, from the base layer 4 side, for example, an intrinsic emitter layer and an emitter mesa layer formed on the intrinsic emitter layer. The intrinsic emitter layer is an n-type InGaP (indium gallium phosphide) layer, the thickness of which is, for example, 30 nm or more and 40 nm or less (i.e., from 30 nm to 40 nm). The emitter mesa layer includes a high concentration n-type GaAs layer and a high concentration n-type InGaAs layer. The thickness of each of the high concentration n-type GaAs layer and the high concentration n-type InGaAs layer is, for example, 100 nm or so. The high concentration n-type InGaAs layer of the emitter mesa layer is formed to achieve ohmic contact with the emitter electrode 6.

The base layer 4 and the collector layer 3 are epitaxially grown on the semiconductor substrate 1 and then etched to form the mesa structures. Note that mesa structures may be formed by the base layer 4 and an upper part of the collector layer 3 without removing a lower part of the collector layer 3.

The collector electrode (illustration of which is omitted) is in contact with the sub-collector layer 2 and formed on the sub-collector layer 2. The collector electrode is located next to, for example, the mesa structure (the base layer 4 and the collector layer 3) in the X-axis direction Dx. The collector electrode includes a lamination film in which, for example, a AuGe (gold germanium) film, a Ni (nickel) film, and a Au (gold) film are laminated in this order. The film thickness of the AuGe film is, for example, 60 nm. The film thickness of the Ni film is, for example, 10 nm. The film thickness of the Au film is, for example, 200 nm.

The base electrode (illustration of which is omitted) is in contact with the base layer 4 and is located on the base layer 4. The base electrode is a lamination film including a Ti film, a Pt film, and a Au film laminated in this order. The film thickness of the Ti film is, for example, 50 nm. The film thickness of the Pt film is, for example, 50 nm. The film thickness of the Au film is, for example, 200 nm.

The emitter electrode 6 is in contact with the emitter layer 5 and is located on the emitter layer 5. The emitter electrode 6 is, for example, a Ti (titanium) film. The film thickness of the Ti film is, for example, 50 nm.

Note that an isolation region 2b is formed next to the sub-collector layer 2 on the semiconductor substrate 1. The isolation region 2b becomes insulating by an ion implantation technique. The isolation region 2b insulates elements (the plurality of transistors BT) from one another.

A first insulating film 9 is formed on the sub-collector layer 2 and the isolation region 2b so as to cover the plurality of transistors BT except parts of the emitter electrodes 6. The first insulating film 9 is, for example, a SiN (silicon nitride) layer. The first insulating film 9 may have a single layer or a plurality of laminated nitride or oxide layers. Emitter wiring 12 composed of a metal is laminated on the first insulating film 9. The emitter wiring 12 is located between the plurality of transistors BT. In plan view in the direction perpendicular to the semiconductor substrate 1, first-insulating-film openings 10 are formed in the first insulating film 9 in regions overlapping the emitter electrodes 6. The bump 21 is electrically connected to the emitter electrodes 6 through the first-insulating-film openings 10.

An inorganic insulating film 14 (passivation film) is formed so as to cover part of the emitter wiring 12. In addition, the first organic insulating film 16 is formed on the inorganic insulating film 14. The inorganic insulating film 14 is an inorganic protective film composed of an inorganic material containing, for example, at least one of SiN or SiON (silicon oxynitride). Note that the inorganic insulating film 14 can be omitted as necessary.

The first organic insulating film 16 is an organic protective film composed of, for example, an organic material such as polyimide and BCB. The inorganic insulating film 14 and the first organic insulating film 16 have openings 15 and 17, respectively, in regions overlapping the plurality of transistors BT and the emitter electrodes 6.

The bump 21 is formed in a region overlapping the opening 15 of the inorganic insulating film 14 and the opening 17 of the first organic insulating film 16 and is electrically connected to the emitter electrodes 6 of the plurality of transistors BT through the openings 15 and 17. The bump 21 is composed of pillar bumps the material of which is, for example, copper (Cu). As for the material for the bump 21, a low resistance metal material such as aluminum (Al) and gold (Au) can be used other than Cu.

Note that although illustration is omitted in FIG. 2, a metal film such as a diffusion prevention layer and a seed layer for plating may be formed between the bump 21 and the emitter wiring 12. The diffusion prevention layer and the seed layer can be composed of a material such as nickel (Ni), titanium (Ti), tungsten (W), or chromium (Cr), for example.

The width R1 of the bump 21 in the X-axis direction Dx is smaller than the width R2 of the opening 17 of the first organic insulating film 16 in the X-axis direction Dx. The outer peripheral surface of the bump 21 is away from and faces the inner peripheral surface of the opening 17 of the first organic insulating film 16. The bump 21 extends with a uniform width R1 from the inside of the opening 17 of the first organic insulating film 16 to a position higher than the first organic insulating film 16. The width R1 of the bump 21 in the X-axis direction Dx is the same as the width of the opening 15 of the inorganic insulating film 14 in the X-axis direction Dx. A lower end portion of the outer peripheral surface of the bump 21 is in contact with the inner peripheral surface of the opening 15 of the inorganic insulating film 14. In other words, the inorganic insulating film 14 covers a surface of the emitter wiring 12 between the bump 21 and the first organic insulating film 16.

Note that in the case in which the width RI of the bump 21 in the X-axis direction Dx has some variations above the first organic insulating film 16, the width R1 may refer to any width within the variations. The width of the opening 17 of the first organic insulating film 16 in the X-axis direction Dx refers to the distance in the X-axis direction Dx between portions of the inner peripheral surface, facing each other, of the first organic insulating film 16 forming the opening 17. The gap between the outer peripheral surface of the bump 21 and the inner peripheral surface of the opening 17 of the first organic insulating film 16 may be filled with, for example, an inorganic insulating film or a metal film.

As illustrated in FIG. 1, the width of the bump 21 in the Y-axis direction Dy is smaller than the width of the opening 17 of the first organic insulating film 16 in the Y-axis direction Dy. The outer peripheral surface of the bump 21 in the Y-axis direction Dy is away from and faces the inner peripheral surface of the opening 17 of the first organic insulating film 16.

As described above, the semiconductor device 100 of the present embodiment includes: a semiconductor substrate 1; at least one transistor BT located on the semiconductor substrate 1 and including a plurality of semiconductor layers; an electrode (for example, an emitter electrode 6) provided for the transistor BT; a first organic insulating film 16 having an opening 17 in a region overlapping the transistor BT and the electrode; and a bump 21 located over the at least one transistor BT and electrically connected to the electrode through the opening 17 of the first organic insulating film 16. The width R1 of the bump 21 in the X-axis direction Dx parallel to the semiconductor substrate 1 is smaller than the width R2 of the opening 17 of the first organic insulating film 16 in the X-axis direction Dx.

In the semiconductor device 100 with this configuration, the bump 21 covers the entire region of the mesa structures of the plurality of transistors BT, and this improves the heat dissipation characteristics. When the semiconductor device 100 is mounted on an external substrate such as a printed circuit board, thermal stress is generated and exerted on the mesa structures of the plurality of transistors BT through the bump 21. In the present embodiment, the width R1 of the bump 21 is smaller than the width R2 of the opening 17 of the first organic insulating film 16. Hence, as compared with the configuration in which the width R1 of the bump 21 is larger than the width R2 of the opening 17 of the first organic insulating film 16, and part of the bump 21 is located on the first organic insulating film 16, the present embodiment can reduce the thermal stress exerted on the mesa structures of the transistors BT through the bump 21.

More specifically, the bump 21 is not located in the region overlapping the inner peripheral surface of the opening 17 of the first organic insulating film 16. Hence, as compared with the configuration in which part of the bump 21 is located on the first organic insulating film 16, the present embodiment can reduce the concentration of thermal stress from the bump 21, near the opening 17 of the first organic insulating film 16. This in turn reduces the concentration of thermal stress on part of the mesa structures of the transistors BT and suppresses the occurrence of a crack in the mesa structures of the transistors BT.

Note that each transistor BT and the bump 21 illustrated in FIGS. 1 and 2 are merely schematic illustration, and hence the shapes and the like can be changed as appropriate. For example, although the bump 21 is illustrated to have a quadrangular cross section, the bump 21 may have another shape such as the one the upper surface of which is curved.

### Second Embodiment

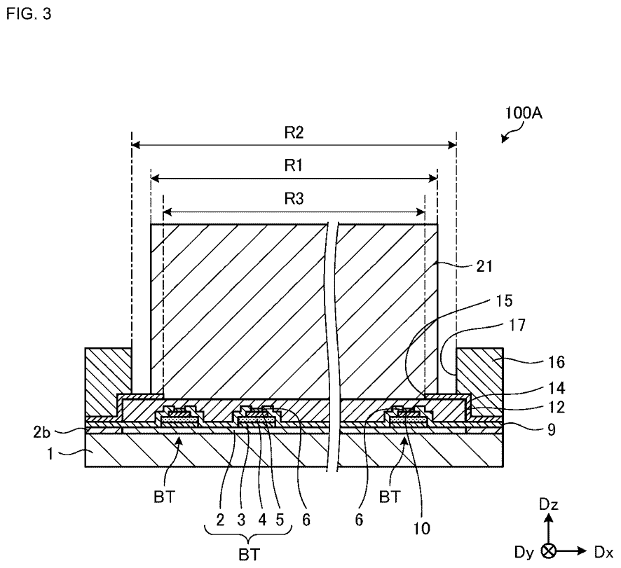

FIG. 3 is a cross-sectional view of a semiconductor device according to a second embodiment. As illustrated in FIG. 3, the second embodiment describes a configuration in which the width R3 of the opening 15 of the inorganic insulating film 14 in the X-axis direction Dx is smaller than the width R1 of the bump 21, unlike the first embodiment described above. Note that the configuration of the transistor group Q1 (the plurality of transistors BT) is the same as or similar to that of the first embodiment, and hence repetitive description is omitted.

As illustrated in FIG. 3, in a semiconductor device 100A according to the second embodiment, the bump 21 overlaps the peripheral edge portion of the opening 15 of the inorganic insulating film 14. With this configuration, the inorganic insulating film 14 covers the entire part of the surface of the emitter wiring 12 between the bump 21 and the first organic insulating film 16. This suppresses entry of water into the semiconductor device 100A from the bump 21 side, and hence the semiconductor device 100A has excellent moisture resistance.

The inorganic insulating film 14 is formed of an inorganic material as described above and has a higher Young's modulus than the first organic insulating film 16. In other words, the inorganic insulating film 14 is apt to transmit the stress from the bump 21 to the transistors BT. Hence, even in the case in which the width R3 of the opening 15 of the inorganic insulating film 14 is small, the occurrence of stress concentration can be suppressed.

### Third Embodiment

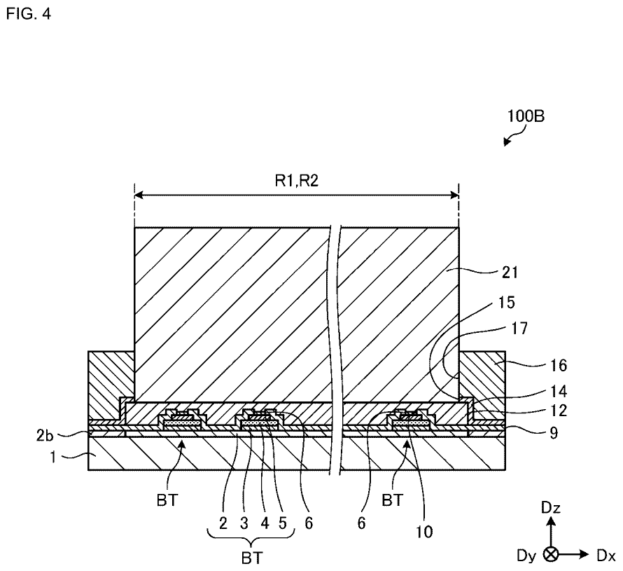

FIG. 4 is a cross-sectional view of a semiconductor device according to a third embodiment. As illustrated in FIG. 4, the third embodiment describes a configuration in which the width R1 of the bump 21 in the X-axis direction Dx is equal to the width R2 of the opening 17 of the first organic insulating film 16 in the X-axis direction Dx, unlike the first and second embodiments described above.

As illustrated in FIG. 4, in a semiconductor device 100B according to the third embodiment, the outer peripheral surface of the bump 21 is in contact with the inner peripheral surface of the opening 17 of the first organic insulating film 16. The bump 21 extends with a uniform width R1 from the inside of the opening 17 of the first organic insulating film 16 to a position higher than the first organic insulating film 16. The opening 15 of the inorganic insulating film 14 has a width equal to the width R2 of the opening 17 of the first organic insulating film 16. However, the present disclosure is not limited to this configuration. As in the second embodiment, the opening 15 of the inorganic insulating film 14 may be smaller than the width R2 of the opening 17 of the first organic insulating film 16.

Also in the present embodiment, the bump 21 is not present on the first organic insulating film 16 in a region outside the opening 17 of the first organic insulating film 16. Hence, as compared with the configuration in which the width R1 of the bump 21 is larger than the width R2 of the opening 17 of the first organic insulating film 16, the present embodiment can reduce the thermal stress exerted on the mesa structures of the transistors BT.

### Fourth Embodiment

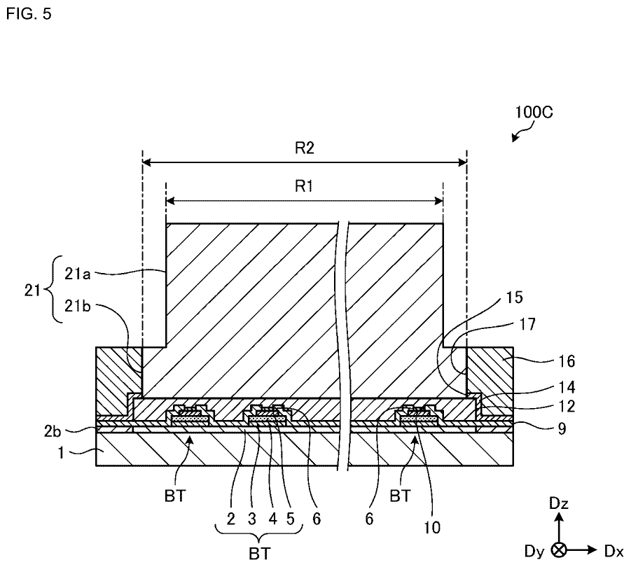

FIG. 5 is a cross-sectional view of a semiconductor device according to a fourth embodiment. As illustrated in FIG. 5, the fourth embodiment describes a configuration in which the bump 21 includes a first portion 21a and a second portion 21b having different widths, unlike the first to third embodiments described above.

As illustrated in FIG. 5, in a semiconductor device 100C according to the fourth embodiment, the bump 21 includes the second portion 21b and the first portion 21a laminated in this order over the plurality of transistors BT. The width R1 of the first portion 21a in the X-axis direction Dx is smaller than the width R2 of the opening 17 of the first organic insulating film 16 in the X-axis direction Dx. Note that in the case in which the width R1 of the first portion 21a in the X-axis direction Dx has some variations above the first organic insulating film 16, the width R1 may refer to any width within the variations.

The second portion 21b is located between the first portion 21a and the transistors BT in the Z-axis direction Dz and inside the opening 17 of the first organic insulating film 16. The second portion 21b is formed by filling the opening 17 of the first organic insulating film 16, and the outer peripheral surface of the second portion 21b is in contact with the inner peripheral surface of the opening 17 of the first organic insulating film 16. In other words, the width of the second portion 21b is larger than the width of the first portion 21a and equal to the width R2 of the opening 17 of the first organic insulating film 16.

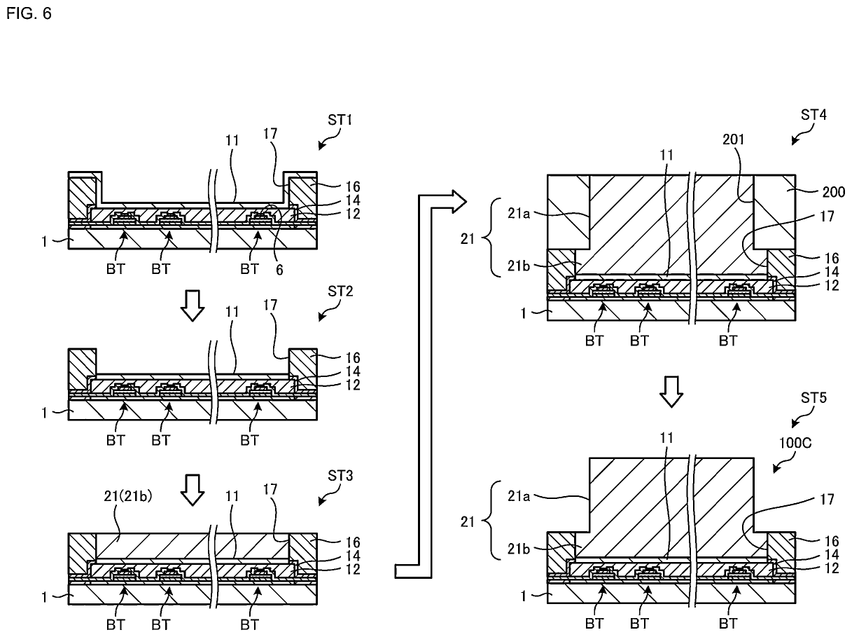

FIG. 6 is an explanatory diagram for explaining manufacturing processes for the semiconductor device according to the fourth embodiment. As illustrated in FIG. 6, the plurality of transistors BT and the insulating films are formed on the semiconductor substrate 1, and then a power supply film 11 is formed so as to cover the plurality of transistors BT and the insulating films (step ST1). The power supply film 11 covers the first organic insulating film 16 and the opening 17 and is in contact with the emitter electrodes 6 of the plurality of transistors BT at the bottom of the opening 17. The power supply film 11 is composed of a metal material having favorable conductivity. Note that illustration of the power supply film 11 is omitted in FIGS. 2 to FIG. 5 described above.

Next, the portion of the power supply film 11 on the first organic insulating film 16 is removed (step ST2). The portion of the power supply film 11 at the bottom of the opening 17 is not removed and left. For example, etching is performed to remove a specified portion of the power supply film 11 on the first organic insulating film 16.

Next, the second portion 21b of the bump 21 is formed inside the opening 17 of the first organic insulating film 16 (step ST3). The second portion 21b of the bump 21 is formed by, for example, plating.

Next, a resist 200 is applied and formed on the first organic insulating film 16 and the second portion 21b, and an opening 201 is formed in a region of the resist 200 overlapping part of the second portion 21b by photolithography. The first portion 21a of the bump 21 is formed inside the opening 201 of the resist 200 (step ST4). The first portion 21a of the bump 21 is formed by, for example, plating.

After that, the resist 200 is removed, so that the bump 21 including the first portion 21a and the second portion 21b is formed (step ST5). As described above, in the method of manufacturing the semiconductor device 100C according to the fourth embodiment, two separate plating processes are performed to form the bump 21 including the first portion 21a and the second portion 21b.

### Fifth Embodiment

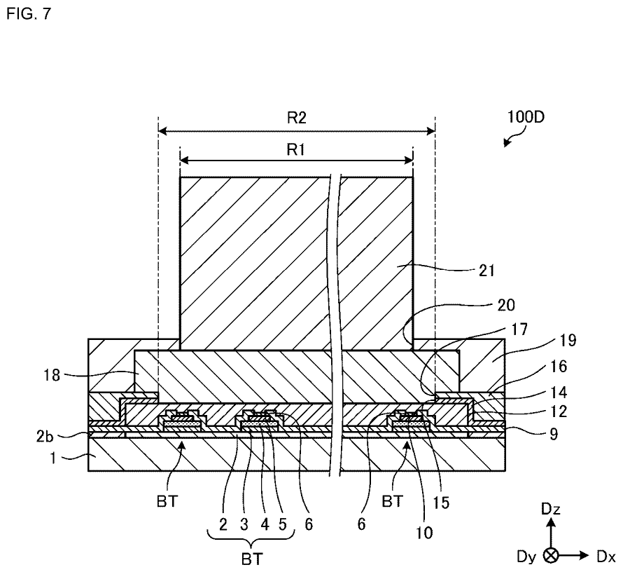

FIG. 7 is a cross-sectional view of a semiconductor device according to a fifth embodiment. As illustrated in FIG. 7, the fifth embodiment describes a configuration including a redistribution layer 18, unlike the first to fourth embodiments described above.

As illustrated in FIG. 7, in a semiconductor device 100D according to the fifth embodiment, the redistribution layer 18 is formed on the first organic insulating film 16 and electrically connected to the plurality of transistors BT through the opening 17.

A second organic insulating film 19 is formed on the first organic insulating film 16 so as to cover the redistribution layer 18. An opening 20 is formed in a region of the second organic insulating film 19 overlapping the redistribution layer 18. The bump 21 is formed in a region overlapping the opening 20 and electrically connected to the redistribution layer 18 through the opening 20. Note that the first organic insulating film 16 and the second organic insulating film 19 may be formed of the same material. In other words, the first organic insulating film 16 and the second organic insulating film 19 may be formed integrally so as not to have a distinct interface between these films.

The width R1 of the bump 21 in the X-axis direction Dx is equal to the width of the opening 20 of the second organic insulating film 19 in the X-axis direction Dx. The width R1 of the bump 21 in the X-axis direction Dx is smaller than the width R2 of the opening 17 of the first organic insulating film 16 in the X-axis direction Dx. In other words, the width of the opening 20 of the second organic insulating film 19 is smaller than the width R2 of the opening 17 of the first organic insulating film 16 in the X-axis direction Dx.

As described above, the semiconductor device 100D according to the fifth embodiment includes the redistribution layer 18 located over at least one transistor BT and also includes the first organic insulating film 16 and the second organic insulating film 19 laminated in this order from the side closer to the transistors BT. The redistribution layer 18 is located between the first organic insulating film 16 and the second organic insulating film 19 and electrically connected to the emitter electrode 6 of the transistor BT through the opening 17 (the first opening) formed in the first organic insulating film 16. The bump 21 is electrically connected to the redistribution layer 18 through the opening 20 (the second opening) formed in the second organic insulating film 19. The width R1 of the bump 21 in the X-axis direction Dx is smaller than the width R2 of the opening 17 of the first organic insulating film 16 in the X-axis direction Dx.

In the configuration including the redistribution layer 18 as described above, the width R1 of the bump 21 is smaller than the width R2 of the opening 17 of the first organic insulating film 16, which is closer to the transistors BT, of the plurality of organic insulating films: the first organic insulating film 16 and the second organic insulating film 19. Hence, this configuration can reduce the thermal stress exerted from the bump 21 on the mesa structures of the transistors BT as in the foregoing embodiments.

### Modification Example

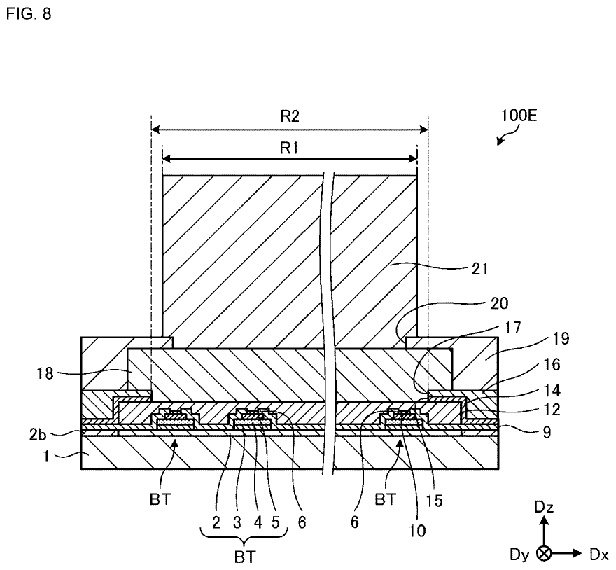

FIG. 8 is a cross-sectional view of a semiconductor device according to a modification example of the fifth embodiment. In the semiconductor device 100D according to the fifth embodiment illustrated in FIG. 7, the width R1 of the bump 21 is not limited to being equal to the width of the opening 20 of the second organic insulating film 19. As illustrated in FIG. 8, in a semiconductor device 100E according to the modification example of the fifth embodiment, the width R1 of the bump 21 may be larger than the width of the opening 20 of the second organic insulating film 19 and smaller than the width R2 of the opening 17 of the first organic insulating film 16.

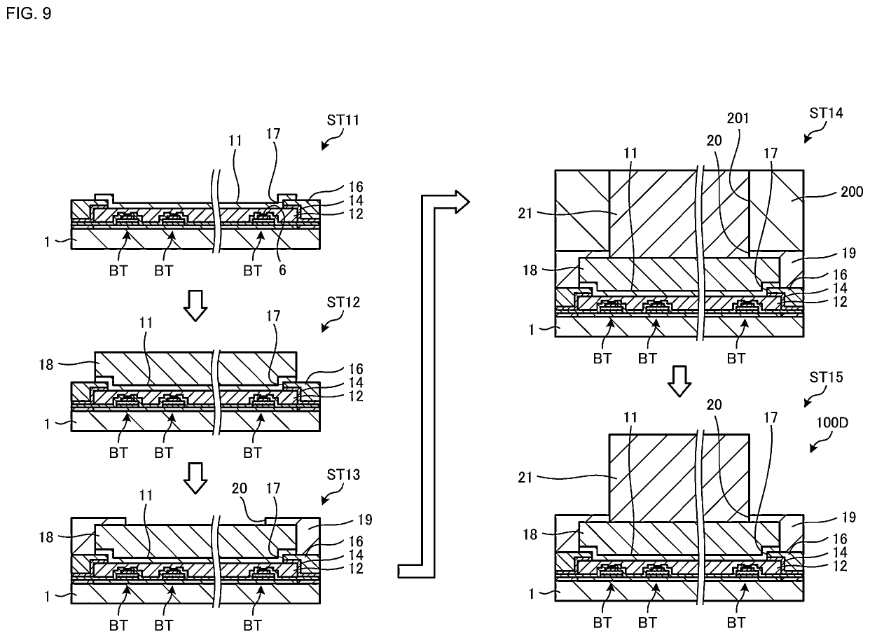

FIG. 9 is an explanatory diagram for explaining manufacturing processes for the semiconductor device according to the fifth embodiment. As illustrated in FIG. 9, the power supply film 11 is formed so as to cover the plurality of transistors BT and the insulating films (step ST11). The power supply film 11 covers the first organic insulating film 16 and the opening 17 and is in contact with the emitter electrodes 6 of the plurality of transistors BT at the bottom of the opening 17. The power supply film 11 is patterned by etching or the like. Specifically, the power supply film 11 is formed such that outer edge portions of the power supply film 11 on the first organic insulating film 16 are removed, and the power supply film 11 covers part of the upper surface of the first organic insulating film 16 near the opening 17.

Next, the redistribution layer 18 is formed on the power supply film 11 so as to cover the opening 17 of the first organic insulating film 16 (step ST12). The redistribution layer 18 is formed by, for example, plating.

Next, the second organic insulating film 19 is formed so as to cover the redistribution layer 18 and the first organic insulating film 16, and the opening 20 is formed in a region of the second organic insulating film 19 overlapping part of the redistribution layer 18 (step ST13). The width of the opening 20 of the second organic insulating film 19 is smaller than the width of the opening 17 of the first organic insulating film 16.

Next, a resist 200 is applied and formed on the second organic insulating film 19 and the redistribution layer 18, and the opening 201 is formed in a region of the resist 200 overlapping the opening 20 of the second organic insulating film 19 by photolithography. The bump 21 is formed inside the opening 201 of the resist 200 (step ST14). The bump 21 is formed by, for example, plating. The width of the opening 201 of the resist 200 is equal to the width of the opening 20 of the second organic insulating film 19. Hence, the width R1 of the bump 21 is equal to the width of the opening 20 of the second organic insulating film 19.

After that, the resist 200 is removed, so that the bump 21 is formed (step ST15). As described above, the redistribution layer 18 and the bump 21 can be formed by the method of manufacturing the semiconductor device 100D according to the fifth embodiment.

Note that the manufacturing processes illustrated in FIG. 9 are a mere example and can be changed as appropriate. For example, in step ST14, the resist 200 may be formed such that the width of the opening 201 is larger than the width of the opening 20 of the second organic insulating film 19 and smaller than the width R2 of the opening 17 of the first organic insulating film 16. In this case, the bump 21 is formed such that the width R1 of the bump 21 is larger than the width of the opening 20 of the second organic insulating film 19 and smaller than the width R2 of the opening 17 of the first organic insulating film 16.

### Sixth Embodiment

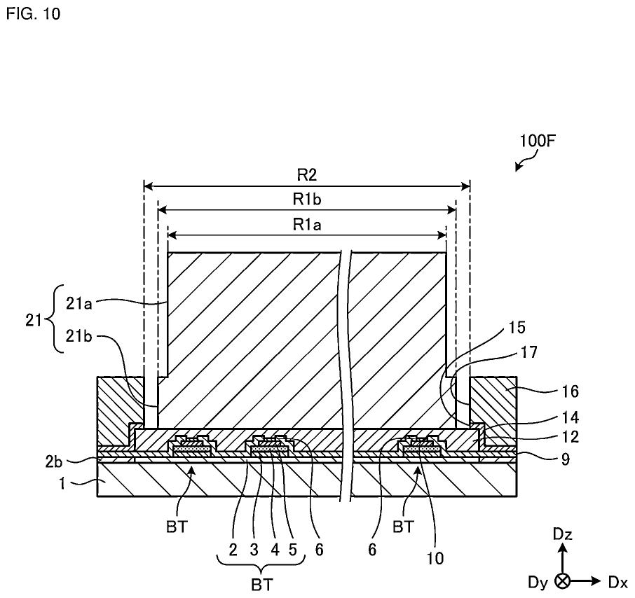

FIG. 10 is a cross-sectional view of a semiconductor device according to a sixth embodiment. As illustrated in FIG. 10, a semiconductor device 100F according to the sixth embodiment differs from the semiconductor device 100C (see FIG. 5) of the fourth embodiment in that the width R1b of the second portion 21b of the bump 21 is smaller than the width R2 of the opening 17 of the first organic insulating film 16. The semiconductor device 100F according to the sixth embodiment can also be said to be a combination of the semiconductor device 100 according to the first embodiment and the bump 21 of the fourth embodiment.

As illustrated in FIG. 10, in the semiconductor device 100F according to the sixth embodiment, the bump 21 includes a first portion 21a and a second portion 21b having different widths. In the bump 21, the second portion 21b and the first portion 21a are laminated in this order over the plurality of transistors BT. The width R1a of the first portion 21a in the X-axis direction Dx is smaller than the width R1b of the second portion 21b. The width R1a of the first portion 21a in the X-axis direction Dx is smaller than the width R2 of the opening 17 of the first organic insulating film 16 in the X-axis direction Dx.

The second portion 21b is located between the first portion 21a and the transistors BT in the Z-axis direction Dz and inside the opening 17 of the first organic insulating film 16. The outer peripheral surface of the second portion 21b faces the inner peripheral surface of the opening 17 of the first organic insulating film 16 with a gap in between. In other words, the width R1b of the second portion 21b is larger than the width of the first portion 21a and smaller than the width R2 of the opening 17 of the first organic insulating film 16.

### Seventh Embodiment

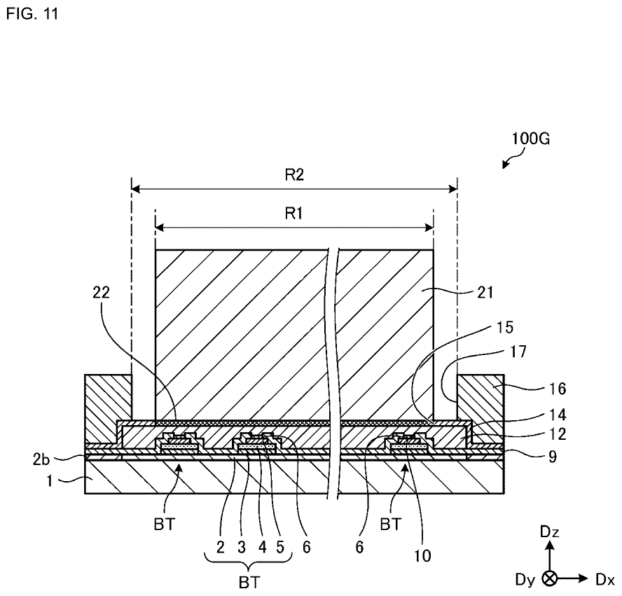

FIG. 11 is a cross-sectional view of a semiconductor device according to a seventh embodiment. As illustrated in FIG. 11, a semiconductor device 100G according to the seventh embodiment differs from the semiconductor device 100 according to the first embodiment in that the semiconductor device 100G includes an under-bump metal 22 (UBM).

The under-bump metal 22 is formed under the bump 21. More specifically, the under-bump metal 22 is formed between the bump 21 and the emitter wiring 12 in the direction perpendicular to the semiconductor substrate 1. In the case in which the width R1 of the bump 21 in the X-axis direction Dx is smaller than the width of the opening 17 of the first organic insulating film 16 in the X-axis direction Dx, also the width of the under-bump metal 22 in the X-axis direction Dx is smaller than the width R2 of the opening 17 of the first organic insulating film 16.

The under-bump metal 22 is formed of, for example, a material containing at least one of Ti, Cr, Cu, Au, Ni, and Pd. Another adhesion layer or the like may be formed between the under-bump metal 22 and the emitter wiring 12. For example, when the semiconductor device 100G of the present embodiment is mounted on an external substrate via the bump21, the bump 21 is compressed by the pressure when mounted, and the width R1 of the bump 21 sometimes becomes larger than the width R2 of the opening 17 of the first organic insulating film 16. Even in such a case, the width of the under-bump metal 22 being smaller than the width R2 of the opening 17 of the first organic insulating film 16 has the same meaning as the width R1 of the bump 21 of the semiconductor device 100G before mounted being smaller than the width R2 of the opening 17 of the first organic insulating film 16. Hence, this configuration can reduce the thermal stress exerted from the bump 21 on the mesa structures of the transistors BT as described above.

Note that although the semiconductor device 100G illustrated in FIG. 11 is a combination of the semiconductor device 100 according to the first embodiment and the under-bump metal 22, the present disclosure is not limited to this configuration. The under-bump metal 22 can be combined with each of the semiconductor devices 100A, 100B, 100C, 100D, 100E, and 100F according to the second to sixth embodiments.

The embodiments described above are based on examples of semiconductor devices in which one bump 21 is located over the plurality of transistors BT, but the present disclosure is not limited to such configurations. The present disclosure may be applied to semiconductor devices in which one bump is formed over one transistor. Although the above description is based on examples in which the bump is composed of pillar bumps, instead of pillar bumps, for example, solder bumps and stud bumps may be employed.

The material, thickness, dimensions, and the like of the constituents, mentioned in the embodiments described above are mere examples and may be changed as appropriate. The material and thickness of the sub-collector layer 2, the collector layer 3, the base layer 4, the emitter layer 5, and various types of wiring may be changed as appropriate.

Note that the embodiments described above are to facilitate understanding of the present disclosure and are not intended to limit interpretation of the present disclosure. The present disclosure can be changed or improved without departing from the spirit thereof, and the present disclosure includes also equivalents thereof.

What is claimed is:

1. A semiconductor device comprising:
a semiconductor substrate;
at least one transistor on the semiconductor substrate and including a plurality of semiconductor layers;
an electrode for the transistor;
an organic insulating film having an opening in a region overlapping the transistor and the electrode in plan view in a first direction perpendicular to the semiconductor substrate; and
a bump over the at least one transistor in plan view in the first direction and electrically connected to the electrode through the opening of the organic insulating film, wherein
a width of the bump in a second direction parallel to the semiconductor substrate is smaller than a width of the opening of the organic insulating film in the second direction.

2. The semiconductor device according to claim 1, wherein
the at least one transistor includes a plurality of transistors that are aligned in the second direction, and
the bump and the opening of the organic insulating film extend over the plurality of transistors.

3. The semiconductor device according to claim 1, further comprising:
an inorganic insulating film between the semiconductor substrate and the organic insulating film, wherein
the inorganic insulating film has an opening in a region overlapping the opening of the organic insulating film and the bump in plan view in the first direction, and
the bump overlaps a peripheral edge portion of the opening of the inorganic insulating film.

4. The semiconductor device according to claim 1, wherein
the bump includes
a first portion, and
a second portion inside the opening of the organic insulating film and between the first portion and the transistor in the first direction, and
a width of the first portion of the bump is smaller than a width of the second portion of the bump.

5. The semiconductor device according to claim 1, further comprising:
a redistribution layer over the at least one transistor in plan view in the first direction, wherein
the organic insulating film includes a first organic insulating film and a second organic insulating film laminated in this order from a side closer to the transistor,
the redistribution layer is between the first organic insulating film and the second organic insulating film and electrically connected to the electrode through a first opening formed in the first organic insulating film,
the bump is electrically connected to the redistribution layer through a second opening formed in the second organic insulating film, and
the width of the bump in the second direction is smaller than a width of the first opening of the first organic insulating film in the second direction.

6. The semiconductor device according to claim 5, wherein
the width of the first opening of the first organic insulating film in the second direction is larger than a width of the second opening of the second organic insulating film in the second direction.

7. The semiconductor device according to claim 2, further comprising:
an inorganic insulating film between the semiconductor substrate and the organic insulating film, wherein
the inorganic insulating film has an opening in a region overlapping the opening of the organic insulating film and the bump in plan view in the first direction, and
the bump overlaps a peripheral edge portion of the opening of the inorganic insulating film.

8. The semiconductor device according to claim 2, wherein
the bump includes
a first portion, and
a second portion inside the opening of the organic insulating film and between the first portion and the transistor in the first direction, and
a width of the first portion of the bump is smaller than a width of the second portion of the bump.

9. The semiconductor device according to claim 3, wherein
the bump includes
a first portion, and
a second portion inside the opening of the organic insulating film and between the first portion and the transistor in the first direction, and
a width of the first portion of the bump is smaller than a width of the second portion of the bump.

10. The semiconductor device according to claim 7, wherein
the bump includes
a first portion, and
a second portion inside the opening of the organic insulating film and between the first portion and the transistor in the first direction, and
a width of the first portion of the bump is smaller than a width of the second portion of the bump.

11. The semiconductor device according to claim 2, further comprising:
a redistribution layer over the at least one transistor in plan view in the first direction, wherein
the organic insulating film includes a first organic insulating film and a second organic insulating film laminated in this order from a side closer to the transistor,
the redistribution layer is between the first organic insulating film and the second organic insulating film and electrically connected to the electrode through a first opening formed in the first organic insulating film,
the bump is electrically connected to the redistribution layer through a second opening formed in the second organic insulating film, and
the width of the bump in the second direction is smaller than a width of the first opening of the first organic insulating film in the second direction.

12. The semiconductor device according to claim 11, wherein
the width of the first opening of the first organic insulating film in the second direction is larger than a width of the second opening of the second organic insulating film in the second direction.

13. A semiconductor device comprising:
a semiconductor substrate;
at least one transistor on the semiconductor substrate and including a plurality of semiconductor layers;
an electrode for the transistor;
an organic insulating film having an opening in a region overlapping the transistor and the electrode in plan view in a first direction perpendicular to the semiconductor substrate; and
a bump over the at least one transistor in plan view in the first direction and electrically connected to the electrode through the opening of the organic insulating film, wherein
a width of the bump in a second direction parallel to the semiconductor substrate is equal to a width of the opening of the organic insulating film in the second direction.

14. The semiconductor device according to claim 13, wherein
the bump includes
a first portion, and
a second portion inside the opening of the organic insulating film and between the first portion and the transistor in the first direction, and
a width of the first portion of the bump is smaller than a width of the second portion of the bump.
